(19) United States
(12) Patent Application Publication
(10) Pub. No.: US 2026/0310845 A1
(43) Pub. Date: Oct. 8, 2026

(54) SYSTEMS AND METHODS FOR SIMULATION GENERATION MANAGEMENT

(71) Applicant: TOYOTA JIDOSHA KABUSHIKI KAISHA, Toyota-shi (JP)

(72) Inventor: Jeremiah Castillo ABOGANDA, Yokohama-shi (JP)

(73) Assignee: TOYOTA JIDOSHA KABUSHIKI KAISHA, Toyota-shi (JP)

(21) Appl. No.: 19/097,991

(22) Filed: Apr. 2, 2025

(51) Int. Cl. G06F 30/20

(52) U.S. Cl. CPC G06F 30/20

(57) ABSTRACT

Provided are systems, method, and device for automatically manage simulation generations. According to example embodiments, the system may include: a memory storage storing computer-executable instructions; and at least one processor communicatively coupled to the memory storage, wherein the at least one processor may be configured to execute the instructions to: obtain a simulation profile defining information associated with a simulation; determine a level of complexity of the simulation based on the obtained simulation profile; select a simulation generator from among a plurality of simulation generators based on the determined level of complexity of the simulation; and generate the simulation based on the simulation profile using the selected simulation generator.

### TECHNICAL FIELD

Example embodiments of the present disclosure relate to a simulation, and more specifically, to the management of the generation of simulations.

### BACKGROUND

Modern vehicles are capable of performing a wide range of complex functions, such as generating telemetry data, transmitting and receiving data via the internet, providing driving assistance and the like. In order to achieve such functions, associated systems and software may need to be tested in order to ensure that the systems and software function as intended, meet specified requirements, and perform reliably in various scenarios.

In this regard, one aspect of the systems and software testing may involve simulation of environment and terrain surrounding a vehicle (ego vehicle). Such simulation may be generated by a backend simulation generator based on requirements and objectives of the simulations which define the scenario (i.e., environment and terrain) to be simulated.

Here, different scenarios of the simulation may require different levels of detail and complexity of the simulation. For example, a simulation of a scenario involving a flat, straight, and empty road may be low in details and complexity, whereas a simulation of a scenario involving a curved, uneven, and busy road may be high in details and complexity.

### SUMMARY

Example embodiments consistent with the present disclosure allow for appropriate backend systems (simulation generators) to be used to generate simulations with appropriate level of complexities, thereby providing a cost effective, efficient, flexible, and adaptable simulation process across various scenarios and hardware setups.

According to example embodiments, a system is provided. The system may include: a memory storage storing computer-executable instructions; and at least one processor communicatively coupled to the memory storage, wherein the at least one processor may be configured to execute the instructions to: obtain a simulation profile defining information associated with a simulation; determine a level of complexity of the simulation based on the obtained simulation profile; select a simulation generator from among a plurality of simulation generators based on the determined level of complexity of the simulation; and generate the simulation based on the simulation profile using the selected simulation generator.

According to example embodiments, each of the plurality of simulation generators may define a level of fidelity, and wherein the at least one processor may be configured to execute the instructions to select the simulation generator from among the plurality of simulation generators by selecting a simulation generator having a level of fidelity that corresponds to the determined level of complexity of the simulation.

According to example embodiments, the level of fidelity may correlate to a level of resource consumption, and wherein the selected simulation generator may be capable of generating the simulation while having a level of resource consumption that is lowest in comparison to other simulation generators of the plurality of simulation generators.

According to example embodiments, the at least one processor may be configured to execute the instructions to generate the simulation by transmitting the simulation profile to the selected simulation generator, such that the selected simulation generator generates the simulation based on the simulation profile.

According to example embodiments, the information associated with the simulation may include information defining a scenario of the simulation.

According to example embodiments, the simulation may include a simulation associated with a vehicle on a road, and wherein the scenario of the simulation may define an element within the scenario comprising at least one of: a property of the vehicle, a property of the road, an agent around the vehicle, a behavior of the agent, and an environment around the vehicle.

According to example embodiments, the scenario may be defined in a form of a scenario requirement specifying an existence of the element within the scenario, and a scenario objectives specifying an objective associated with the element within the scenario.

According to example embodiments, a method is provided. The method may include: obtaining a simulation profile defining information associated with a simulation; determining a level of complexity of the simulation based on the obtained simulation profile; selecting a simulation generator from among a plurality of simulation generators based on the determined level of complexity of the simulation; and generating the simulation based on the simulation profile using the selected simulation generator.

According to example embodiments, each of the plurality of simulation generators may define a level of fidelity, and wherein the selecting the simulation generator from among the plurality of simulation generators may include selecting a simulation generator having a level of fidelity that corresponds to the determined level of complexity of the simulation.

According to example embodiments, the level of fidelity may correlate to a level of resource consumption, and wherein the selected simulation generator may be capable of generating the simulation while having a level of resource consumption that is lowest in comparison to other simulation generators of the plurality of simulation generators.

According to example embodiments, the generating the simulation may include transmitting the simulation profile to the selected simulation generator, such that the selected simulation generator generates the simulation based on the simulation profile.

According to example embodiments, the information associated with the simulation may include information defining a scenario of the simulation.

According to example embodiments, the simulation may include a simulation associated with a vehicle on a road, and wherein the scenario of the simulation may define an element within the scenario comprising at least one of: a property of the vehicle, a property of the road, an agent around the vehicle, a behavior of the agent, and an environment around the vehicle.

According to example embodiments, the scenario may be defined in a form of a scenario requirement specifying an existence of the element within the scenario, and a scenario objectives specifying an objective associated with the element within the scenario.

According to example embodiments, a non-transitory computer-readable recording medium is provided. The non-transitory computer-readable recording medium may have recorded thereon instructions executable by at least one processor to cause the at least one processor to perform a method including: obtaining a simulation profile defining information associated with a simulation; determining a level of complexity of the simulation based on the obtained simulation profile; selecting a simulation generator from among a plurality of simulation generators based on the determined level of complexity of the simulation; and generating the simulation based on the simulation profile using the selected simulation generator.

According to example embodiments, each of the plurality of simulation generators may define a level of fidelity, and wherein the selecting the simulation generator from among the plurality of simulation generators may include selecting a simulation generator having a level of fidelity that corresponds to the determined level of complexity of the simulation.

According to example embodiments, the level of fidelity may correlate to a level of resource consumption, and wherein the selected simulation generator may be capable of generating the simulation while having a level of resource consumption that is lowest in comparison to other simulation generators of the plurality of simulation generators.

According to example embodiments, the generating the simulation may include transmitting the simulation profile to the selected simulation generator, such that the selected simulation generator generates the simulation based on the simulation profile.

According to example embodiments, the information associated with the simulation may include information defining a scenario of the simulation.

According to example embodiments, the simulation may include a simulation associated with a vehicle on a road, and wherein the scenario of the simulation may define an element within the scenario comprising at least one of: a property of the vehicle, a property of the road, an agent around the vehicle, a behavior of the agent, and an environment around the vehicle.

Additional aspects will be set forth in part in the description that follows and, in part, will be apparent from the description, or may be realized by practice of the presented embodiments of the disclosure.

### BRIEF DESCRIPTION OF THE DRAWINGS

Features, aspects, and advantages of embodiments of the disclosure will be described below with reference to the accompanying drawings, in which like reference numerals denote like elements, and wherein:

FIG. 1 illustrates a block diagram of an example system configuration for managing simulation generation, according to one or more example embodiments;

FIG. 2 illustrates a flow diagram of an example method for managing a generation of a simulation, according to one or more example embodiments; and

FIG. 3 illustrates a block diagram of example components in a system, according to one or more example embodiments.

### DETAILED DESCRIPTION

The following detailed description of exemplary embodiments refers to the accompanying drawings. The foregoing disclosure provides illustration and description but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, in the flowcharts and descriptions of operations provided below, it is understood that one or more operations may be omitted, one or more operations may be added, one or more operations may be performed simultaneously (at least in part), and the order of one or more operations may be switched.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Where only one item is intended, the term “one” or similar language is used. Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “[A] and/or [B]”, “at least one of [A] and [B]” or “at least one of [A] or [B]” are to be understood as including only A, only B, or both A and B.

Expressions such as “at least one processor,” where configured to implement a plurality of operations, execute a plurality of instructions, etc., are to be understood as a single processor implementing the plurality of operations, etc., or each of plural processors implementing at least some (but not necessarily all) of the plurality of operations, etc.

Reference throughout this specification to “one embodiment,” “an embodiment,” “non-limiting exemplary embodiment,” or similar language means that a particular feature, structure, or characteristic described in connection with the indicated embodiment is included in at least one embodiment of the present solution. Thus, the phrases “in one embodiment”, “in an embodiment,” “in one non-limiting exemplary embodiment,” and similar language throughout this specification may, but do not necessarily, all refer to the same embodiment.

Further, the described features, advantages, and characteristics of the present disclosure may be combined in any suitable manner in one or more example embodiments. One skilled in the relevant art will recognize, in light of the description herein, that the present disclosure can be practiced without one or more of the specific features or advantages of a particular embodiment. In other instances, additional features and advantages may be recognized in certain embodiments that may not be present in all embodiments of the present disclosure.

Furthermore, the term “vehicle” described herein refers to any suitable type of vehicle in which example embodiments of the present disclosure can be implemented. For instance, the “vehicle” may refer to a motorized vehicle such as a car, a truck, a bus, a motorcycle, or any other suitable type of automobile powered by an engine, motor, or other mechanical means. Alternatively or additionally, the “vehicle” described herein may refer to a bicycle, a skateboard, and any other suitable types of non-motorized vehicle, without departing from the scope of the present disclosure.

As explained above, the systems and software testing may involve simulation of environment and terrain surrounding a vehicle (ego vehicle), where such simulation may be generated by a backend simulation generator and where different scenarios of the simulation may require different levels of detail and complexity of the simulation.

In the related art, the backend simulation generator used to generate the simulation is fixed and cannot be changed. As such, a high-fidelity backend simulation generator is usually selected and utilized in order to ensure that simulations with high details and complexity can be generated. However, such high-fidelity backend simulation generator may require a high amount of resources and cost to utilize, which may not be efficient and cost-effective for generating simulations with low details and complexity.

As such, there is a need for a method that enables dynamic switching between backend simulation generators with different fidelity levels to generate simulations with different levels of detail and complexity.

It is contemplated that features, advantages, and significances of example embodiments described herein are merely a portion of the present disclosure, and are not intended to be exhaustive or to limit the scope of the present disclosure. Further descriptions of the features, components, configuration, operations, and implementations of the example embodiments of the present disclosure are provided in the following.

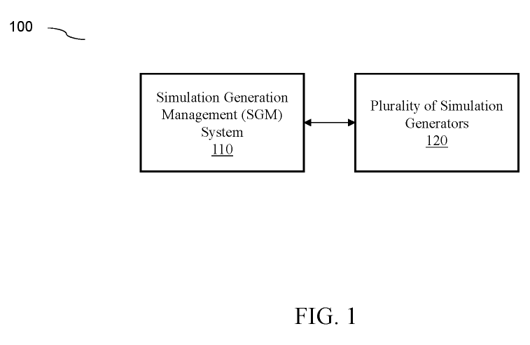

FIG. 1 illustrates a block diagram of an example system configuration 100 for managing simulation generation, according to one or more example embodiments. As illustrated in FIG. 1, system configuration 100 may include a simulation generation management (SGM) system 110 and a plurality of simulation generators 120.

The plurality of simulation generators 120 may include backend algorithms, software, systems, and the like that are configured to generate a simulation. In this regard, the plurality of simulation generators 120 may include any kind of generators for simulations. For example, the plurality of simulation generators 120 may include Environment Simulator Minimalistic (ESMINI), Car Learning to Act (CARLA), and the like.

Further, each of the plurality of simulation generators 120 may define a level of fidelity. The level of fidelity may specify a level of complexity of a simulation that can be generated by a corresponding simulation generator. For example, since the CARLA may not support simulation of complex shapes and elevations of a road and queries to CARLA may return only one position in the map which may be out-of-bounds from the road, the CARLA may be able to generate only a low level of complexity of the simulation. Accordingly, the CARLA may define a low level of fidelity. On the other hand, since the ESMINI may support simulation of complex shapes and elevations of a road and queries to ESMINI may return multiple positions in the map which may not be out-of-bounds from the road, the ESMINI may be able to generate a high level of complexity of the simulation. Accordingly, the ESMINI may define a high level of fidelity.

The SGM system 110 may include an apparatus, a system, a platform, a module, or the like, which may be configured to perform one or more operations or actions for managing a generation of a simulation.

Further, the SGM system 110 may be communicatively coupled to the plurality of simulation generators 120 in order to manage generation of a simulation. For example, the SGM system 110 may transmit an instruction to generate a particular simulation (along with any associated data) to one or more of the plurality of simulation generators 120, where the one or more of the plurality of simulation generators 120 may accordingly generate and provide such particular simulation to the SGM system 110.

Furthermore, the SGM system 110 may communicate with and transmit data to one or more of the plurality of simulation generators 120 using any means. In particular, the SGM system 110 may communicate with the one or more of the plurality of simulation generators 120 using any appropriate interfaces, application programing interfaces (APIs), formats, and the like.

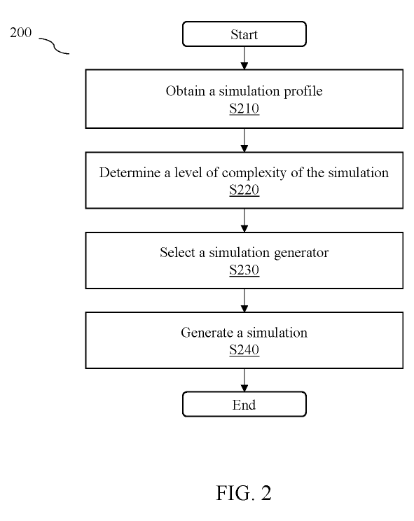

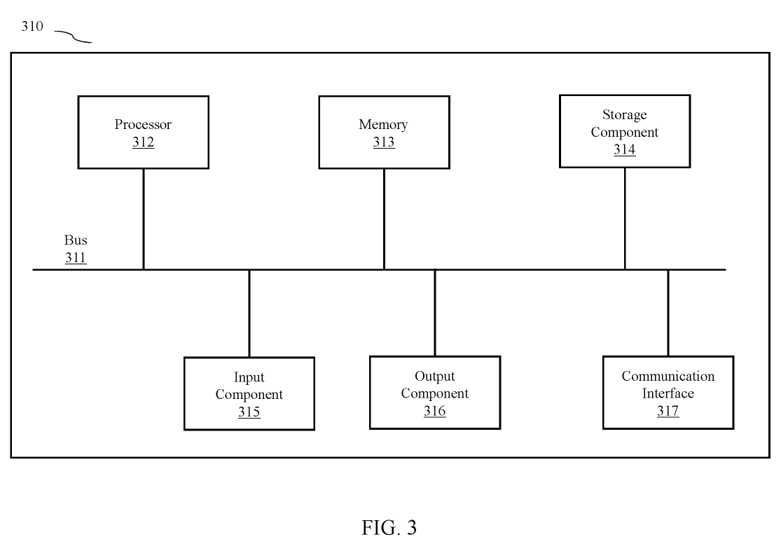

Example operations performable by the SGM system 110 for managing a generation of a simulation are described below with reference to FIG. 2. Further, several example components which may be included in the SGM system 110, according to one or more example embodiments, are described below with reference to FIG. 3.

FIG. 2 illustrates a flow diagram of an example method 200 for managing a generation of a simulation, according to one or more example embodiments. One or more operations in method 200 may be performed by the SGM system. In particular, for example, the at least one processor (e.g., processor 312) of the SGM system may be configured to perform one or more operations in method 200.

As illustrated in FIG. 2, at operation S210, the system may be configured to obtain a simulation profile. The simulation profile may define information associated with a simulation.

According to example embodiments, the simulation may include a simulation associated with a vehicle on a road. Further, the information associated with the simulation may include information defining a scenario of the simulation. According to example embodiments, the scenario of the simulation may define an element within the scenario, which may include at least one of: a property of the vehicle, a property of the road, an agent around the vehicle, a behavior of the agent, and an environment around the vehicle.

For example, the scenario of the simulation may define properties of the vehicle, such as subsystems (e.g., sensors (e.g., LIDAR, accelerometer, GPS, etc.), suspensions, electronic control units (ECUs), and the like), dimension, weight, turning degree/steering characteristics, chassis properties, tires properties, and the like. In another example, the scenario of the simulation may define properties of the road, such as geometry, curvature, width, inclination, declination, friction, number of lanes, additional roads and road network relationships (e.g., intersections), associated speed limits, associated characteristics (e.g., bicycle use), variation of any of the properties (e.g., the road has less width at the curve), and the like. In a further example, the scenario of the simulation may define agents around the vehicle along with their behavior, such as a pedestrian walking along the road parallel to the vehicle, a pedestrian suddenly waking across the vehicle, another vehicle driving behind the vehicle, another vehicle in front of the vehicle suddenly breaking, an obstacle standing still on the road in front of the vehicle, and the like. In a further example, the scenario of the simulation may define environments around the vehicle, such as fog, rain, smoke, day time, night time, and the like.

According to example embodiments, the scenario may be defined in the form of scenario requirements and scenario objectives. The scenario requirements may specify the existence of the element within the scenario (i.e., the property of the vehicle, the property of the road, the agent around the vehicle, the behavior of the agent, and the environment around the vehicle) described above. The scenario objectives may specify the objectives associated with the element within the scenario. For example, the scenario objectives may specify safety related objectives such as the vehicle must not collide with the vehicle in front when the vehicle in front suddenly breaks, the software of the vehicle must provide a warning regarding poor weather conditions, and the vehicle must stay in the lane when curing the curvature of the road, and the like. In another example, the scenario objectives may specify performance related objectives such software performance when the sensors are not working at 100% effectiveness, software accuracy when detecting objects on the road, and the like.

It is understood that the present disclosure is not limited in how the simulation profile is obtained. For example, a user (e.g., software developer, software tester, etc.) may provide the simulation profile to the system. In another example, the system (i.e., SGM system) may be part of a digital twin system, where a separate system models a real world scenario around the vehicle, generates the simulation profile based on such models, and provides the simulation profile to the SGM system. The method then proceeds to operation S220.

At operation S220, the system may be configured to determine a level of complexity of the simulation. The level of complexity of the simulation may be determined based on the obtained simulation profile.

For example, if the scenario of the simulation (indicated in the simulation profile) involves a large number of agents with various behaviors and highly fluctuating properties of the road, the system may determine that the level of complexity of the simulation is high. In another example, if the scenario of the simulation involves only the vehicle and the road where the road is flat and straight with no changes in properties, the system may determine that the level of complexity of the simulation is low.

It is understood that the present disclosure is not limited in how the level of complexity of the simulation is determined based on the obtained simulation profile. For example, the system may utilize machine learning (ML) models trained to recognize and classify the simulation into various levels of complexity based on any of the information associated with the simulation defined/included in the simulation profile. The method then proceeds to operation S230.

At operation S230, the system may be configured to select a simulation generator from among a plurality of simulation generators. The simulation generator may be selected from among the plurality of simulation generators based on the determined level of complexity of the simulation.

The plurality of simulation generators may include backend algorithms, software, systems, and the like that are configured to generate a simulation. In this regard, the plurality of simulation generators may include any kind of generators for simulations, such as Environment Simulator Minimalistic (ESMINI), Car Learning to Act (CARLA), and the like.

Further, each of the plurality of simulation generators may define a level of fidelity. The level of fidelity may indicate a level of complexity of a simulation that can be generated by a corresponding simulation generator. For example, the plurality of simulation generators may include a first simulation generator defining a high level of fidelity, and a second simulation generator defining a low level of fidelity.

In this regard, according to example embodiments, the system may select the simulation generator from among the plurality of simulation generators by selecting a simulation generator having a level of fidelity that corresponds to the determined level of complexity of the simulation. For example, the first simulation generator (which defines a high level of fidelity) may be selected if the determined level of complexity of the simulation is high, while the second simulation generator (which defines a low level of fidelity) may be selected if the determined level of complexity of the simulation is low.

Here, the level of fidelity may correlate to a level of resource (e.g., computational resource) consumption, such that a simulation generator with high level of fidelity would consume a high amount of resources to generate a simulation, while a simulation generator with low level of fidelity would consume a low amount of resources to generate a simulation. As such, the selected simulation generator (which has a level of fidelity that corresponds to the determined level of complexity of the simulation) may be capable of generating the simulation (having the determined level of complexity) while having a level of resource consumption that is lowest in comparison to other simulation generators of the plurality of simulation generators.

For example, the level of fidelity of the simulation generator and the level of complexity of the simulation may be defined in discrete levels 1 to 5 (e.g., 5 being high and 1 being low), where the plurality of simulation generators may include first, second, third, fourth, and fifth simulation generators having levels of fidelity of 1, 2, 3, 4, and 5, respectively. Here, if the level of complexity is determined to be 3, the first and second simulation generators having the level of fidelities of 1 and 2 would not be capable of generating the simulation and would not be selected. In this regard, from among the remaining third, fourth, and fifth simulation generators having the level of fidelities of 3, 4, and 5, the third simulation generator having the level of fidelity of 3 would consume the lowest amount of resources in comparison to the fourth and fifth simulation generators having the level of fidelity of 4 and 5. As such, the third simulation generator having the level of fidelity of 3 may be selected during operation S230.

It is understood that the present disclosure is not limited in how the level of fidelity of the simulation generator and the level of complexity of simulation are defined and determined, as long as the fidelity of the simulation generator and the complexity of simulation can be measured and be distinguished from one another, and as long as a correspondence between different fidelities of the simulation generator and different complexities of simulation can be established. For example, the level of fidelity and the level of complexity may be defined in discrete levels 1 to 5 as described above. In another example, a machine learning model may be trained to recognize various degrees of fidelities of simulation generators and various degrees of complexities of simulations, where such machine learning model may be used to select a simulation generator having a degree (level) of fidelity that corresponds to the determined degree (level) of complexity of the simulation.

According to example embodiments, the system may include any kind of algorithm, software, application, and the like that selects/switches a simulation generator from among a plurality of simulation generators based on the determined level of complexity of the simulation. The method then proceeds to operation S240.

At operation S240, the system may be configured to generate the simulation (i.e., the simulation defined in the simulation profile). The simulation may be generated using the selected simulation generator.

In particular, according to example embodiments, the system may generate the simulation by transmitting the simulation profile to the selected simulation generator, such that the selected simulation generator generates the simulation based on the simulation profile. For example, if the first simulation generator is selected, the system may transmit the simulation profile to the first simulation generator, such that the first simulation generator may generate the simulation using the information defined in the simulation profile.

According to example embodiments, the system may generate the simulation by further analyzing the simulation profile to identify the scenario of the simulation, and transmitting the result of the analysis to the selected simulation generator as settings for the generation of the simulation. The result of the analysis may include scenario requirements and/or scenario objectives associated with the scenario. For example, the system may analyze the simulation profile and identify that the scenario involves a flat and straight road with no changes in properties. As such, for example, the system may transmit a simulation settings specifying a configuration of the simulation involving a flat and straight road with no changes in properties to the first simulation generator, where the first simulation generator may generate the simulation based on such simulation settings.

Upon performing operation S240, the method 200 may be ended or be terminated. Alternatively, method 200 may return to operation S210, such that the at least one processor may be configured to repeatedly perform, for at least a predetermined amount of time, the obtaining the simulation profile (at operation S210), the determining the level of complexity of the simulation (at operation S220), the selecting the simulation generator (at operation S230), and the generating the simulation (at operation S240). For instance, the at least one processor may continuously (or periodically) receive new simulation profiles defining information associated with new simulations, and then restart the obtaining the simulation profile (at operation S210), the determining the level of complexity of the simulation (at operation S220), the selecting the simulation generator (at operation S230), and the generating the simulation (at operation S240).

Accordingly, the above processes allow for appropriate backend systems (simulation generators) to be used to generate simulations with appropriate levels of complexity, thereby providing a cost effective, efficient, flexible, and adaptable simulation process across various scenarios and hardware setups.

FIG. 3 illustrates a block diagram of example components in a system 300, according to one or more example embodiments. The system 300 may correspond to the SGM system 110 in FIG. 1, thus the features associated with the SGM system 110 and the system 300 may be similarly applicable to each other, unless being explicitly described otherwise.

As illustrated in FIG. 3, the system 310 may include at least one bus 311, at least one processor 312, at least one memory 313, at least one storage component 314, at least one input component 315, at least one output component 316, and at least one communication interface 317.

It is contemplated that the system 310 may include more or less components than illustrated in FIG. 3, without departing from the scope of the present disclosure. For instance, in some embodiments, the system 310 may include a plurality of storage components 314, the input component 315 and the output component 316 may be implemented as a transceiver component, the memory 313 and storage component 314 may be implemented as a memory storage, and the like.

The bus 311 may be configured to facilitate or enable communications among the components of the system 310. Specifically, the bus 311 may communicatively couple the components to each other and provide a means for data transfer and flow of control signals between the components. The bus 311 may include one or more of: an internal bus, an address bus, a data bus, a control bus, a controller area network (CAN) bus, an Ethernet bus, a peripheral component interconnect express (PCIe) bus, and any other suitable type of bus that can be implemented in the system 310 to enable communication and coordination between the components within the system 310 in real-time (or near real-time).

The processor 312 may be implemented in hardware, firmware, or a combination of hardware and software, and may be configured to handle real-time (or near real-time) data processing and control of the control system 310. The processor 312 may include one or more of: a central processing unit (CPU), a graphics processing unit (GPU), a neural processing unit (NPU), a tensor processing unit (TPU), an accelerated processing unit (APU), a microprocessor, a microcontroller, a digital signal processor (DSP), a field-programmable gate array (FPGA), an application-specific integrated circuit (ASIC), and/or another type of processing or computing component that can be implemented in the system 310. In some implementations, the processor 312 may be capable of being programmed to perform one or more operations described herein. Further, the processor 312 may include a plurality of processing units, each of which is dedicated to performing a specific operation.

The memory 313 may include one or more mediums for storing temporary data, runtime variables, program instructions, and buffers required for the operations of the control system 310. The memory 313 may include one or more of: a flash memory, a read-only memory (ROM), a random-access memory (RAM), a dynamic or static storage device (e.g., a flash memory, a magnetic memory, and/or an optical memory), any other suitable type of memory that can be implemented in the system 310 to store information and/or instructions for use by the processor 312.

The storage component 314 may be configured to store non-volatile data, such as firmware, configuration settings, calibration data, information, and/or software related to the operation and use of the system 310. For example, the storage component 314 may include a hard disk (e.g., a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

According to example embodiments, the storage component 314 may be configured to store computer-readable or computer-executable instructions for implementing one or more operations of the system 310. The storage component 314 may provide the stored information to the memory 313 for the execution of the processor 312.

The input component 315 may include one or more input components that permit the system 310 to receive information, such as via user input (e.g., a touch screen display, a keyboard, a keypad, a mouse, a button, a switch, and/or a microphone). The output component 316 may include one or more output components that provide output information from the system 310 (e.g., a display, a speaker, a navigation device, one or more light-emitting diodes (LEDs), etc.) According to example embodiments, the input component 315 and/or the output component 316 may be optional and may be excluded from the system 310.

The at least one communication interface 317 may include a transceiver-like component (e.g., a transceiver and/or a separate receiver and transmitter) that enables the system 310 to communicate with other components (e.g., ECUs, user devices, etc.), such as via a wired connection, a wireless connection, or a combination of wired and wireless connections. For example, communication interface 317 may include a controller area network (CAN) bus interface, an Ethernet interface, an optical interface, a coaxial interface, an infrared interface, a radio frequency (RF) interface, a universal serial bus (USB) interface, a Wi-Fi interface, a cellular network interface, or the like.

According to one or more embodiments, the communication interface 317 may include at least one input/output (I/O) interface, at least one network interface, at least one storage interface, or the like, that enable the components 312-316 to communicate with other components. Further, the communication interface 317 may include one or more application programming interfaces (APIs) that allow the system 310 (or one or more components included therein) to communicate with one or more software applications (e.g., software application deployed in the ECUs, etc.)

Computer-executable instructions (e.g., software instructions, etc.) may be read into memory 313 and/or storage component 314 from another computer-readable medium or from another device (e.g., a remote server, an external storage, etc.) via, for example, the communication interface 317. When executed, the computer-executable instructions stored in memory 313 and/or storage component 314 may cause the processor 312 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

It is contemplated that features, advantages, and significances of example embodiments described hereinabove are merely a portion of the present disclosure, and are not intended to be exhaustive or to limit the scope of the present disclosure. Further descriptions of the features, components, configuration, operations, and implementations of example embodiments of the present disclosure, as well as the associated technical advantages and significances, are provided in the following.

It is understood that the specific order or hierarchy of blocks in the processes/ flowcharts disclosed herein is an illustration of example approaches. Based upon design preferences, it is understood that the specific order or hierarchy of blocks in the processes/ flowcharts may be rearranged. Further, some blocks may be combined or omitted. The accompanying method claims present elements of the various blocks in a sample order, and are not meant to be limited to the specific order or hierarchy presented.

Some embodiments may relate to a system, a method, and/or a computer-readable medium at any possible technical detail level of integration. Further, as described hereinabove, one or more of the above components described above may be implemented as instructions stored on a computer readable medium and executable by at least one processor (and/or may include at least one processor ). The computer-readable medium may include a computer-readable non-transitory storage medium (or media) having computer-readable program instructions thereon for causing a processor (or processors) to carry out operations.

The computer readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object-oriented programming languages such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a SoC, a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or another device to cause a series of operational steps to be performed on the computer, other programmable apparatus or other device to produce a computer-implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer-readable media according to various embodiments. In this regard, each block in the flowchart or block diagrams may represent a module, segment, or portion of instructions, which comprises one or more executable instructions for implementing the specified logical function(s). The method, computer system, and computer-readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware may be designed to implement the systems and/or methods based on the description herein.

What is claimed is:

1. A system for managing simulation generation, the system comprising:
a memory storage storing computer-executable instructions; and
at least one processor communicatively coupled to the memory storage, wherein the at least one processor is configured to execute the instructions to:
obtain a simulation profile defining information associated with a simulation;
determine a level of complexity of the simulation based on the obtained simulation profile;
select a simulation generator from among a plurality of simulation generators based on the determined level of complexity of the simulation; and
generate the simulation based on the simulation profile using the selected simulation generator.

2. The system according to claim 1, wherein each of the plurality of simulation generators define a level of fidelity, and wherein the at least one processor is configured to execute the instructions to select the simulation generator from among the plurality of simulation generators by selecting a simulation generator having a level of fidelity that corresponds to the determined level of complexity of the simulation.

3. The system according to claim 2, wherein the level of fidelity correlates to a level of resource consumption, and wherein the selected simulation generator is capable of generating the simulation while having a level of resource consumption that is lowest in comparison to other simulation generators of the plurality of simulation generators.

4. The system according to claim 1, wherein the at least one processor is configured to execute the instructions to generate the simulation by transmitting the simulation profile to the selected simulation generator, such that the selected simulation generator generates the simulation based on the simulation profile.

5. The system according to claim 1, wherein the information associated with the simulation comprises information defining a scenario of the simulation.

6. The system according to claim 5, wherein the simulation comprises a simulation associated with a vehicle on a road, and wherein the scenario of the simulation defines an element within the scenario comprising at least one of: a property of the vehicle, a property of the road, an agent around the vehicle, a behavior of the agent, and an environment around the vehicle.

7. The system according to claim 6, wherein the scenario is defined in a form of a scenario requirement specifying an existence of the element within the scenario, and a scenario objectives specifying an objective associated with the element within the scenario.

8. A method comprising:
obtaining a simulation profile defining information associated with a simulation;
determining a level of complexity of the simulation based on the obtained simulation profile;
selecting a simulation generator from among a plurality of simulation generators based on the determined level of complexity of the simulation; and
generating the simulation based on the simulation profile using the selected simulation generator.

9. The method according to claim 8, wherein each of the plurality of simulation generators define a level of fidelity, and wherein the selecting the simulation generator from among the plurality of simulation generators comprises selecting a simulation generator having a level of fidelity that corresponds to the determined level of complexity of the simulation.

10. The method according to claim 9, wherein the level of fidelity correlates to a level of resource consumption, and wherein the selected simulation generator is capable of generating the simulation while having a level of resource consumption that is lowest in comparison to other simulation generators of the plurality of simulation generators.

11. The method according to claim 8, wherein the generating the simulation comprises transmitting the simulation profile to the selected simulation generator, such that the selected simulation generator generates the simulation based on the simulation profile.

12. The method according to claim 8, wherein the information associated with the simulation comprises information defining a scenario of the simulation.

13. The method according to claim 12, wherein the simulation comprises a simulation associated with a vehicle on a road, and wherein the scenario of the simulation defines an element within the scenario comprising at least one of: a property of the vehicle, a property of the road, an agent around the vehicle, a behavior of the agent, and an environment around the vehicle.

14. The method according to claim 13, wherein the scenario is defined in a form of a scenario requirement specifying an existence of the element within the scenario, and a scenario objectives specifying an objective associated with the element within the scenario.

15. A non-transitory computer-readable recording medium having recorded thereon instructions executable by at least one processor to cause the at least one processor to perform a method comprising:
obtaining a simulation profile defining information associated with a simulation;
determining a level of complexity of the simulation based on the obtained simulation profile;
selecting a simulation generator from among a plurality of simulation generators based on the determined level of complexity of the simulation; and
generating the simulation based on the simulation profile using the selected simulation generator.

16. The non-transitory computer-readable recording medium according to claim 15, wherein each of the plurality of simulation generators define a level of fidelity, and wherein the selecting the simulation generator from among the plurality of simulation generators comprises selecting a simulation generator having a level of fidelity that corresponds to the determined level of complexity of the simulation.

17. The non-transitory computer-readable recording medium according to claim 16, wherein the level of fidelity correlates to a level of resource consumption, and wherein the selected simulation generator is capable of generating the simulation while having a level of resource consumption that is lowest in comparison to other simulation generators of the plurality of simulation generators.

18. The non-transitory computer-readable recording medium according to claim 15, wherein the generating the simulation comprises transmitting the simulation profile to the selected simulation generator, such that the selected simulation generator generates the simulation based on the simulation profile.

19. The non-transitory computer-readable recording medium according to claim 15, wherein the information associated with the simulation comprises information defining a scenario of the simulation.

20. The non-transitory computer-readable recording medium according to claim 19, wherein the simulation comprises a simulation associated with a vehicle on a road, and wherein the scenario of the simulation defines an element within the scenario comprising at least one of: a property of the vehicle, a property of the road, an agent around the vehicle, a behavior of the agent, and an environment around the vehicle.
